(19) United States
(12) Patent Application Publication
(10) Pub. No.: US 2015/0194816 A1
(43) Pub. Date: Jul. 9, 2015

(54) ELECTRICALLY POWERED PORTABLE DEVICE

(71) Applicant: HON HAI PRECISION INDUSTRY CO., LTD., New Taipei (TW)

(72) Inventor: SHAO-HAN CHANG, New Taipei (TW)

(21) Appl. No.: 14/496,928

(22) Filed: Sep. 25, 2014

(30) Foreign Application Priority Data
Jan. 3, 2014 (CN) 2014100022551

(51) Int. Cl. H02J 5/00; H05K 5/03; H05K 5/02; H02J 7/02

(52) U.S. Cl. CPC H02J 5/005; H02J 7/025; H05K 5/03; H05K 5/0247

(57) ABSTRACT

An electrically powered portable device powered remotely and wirelessly includes a cover, a main body engaged with the cover, and an induction coil positioned inside the cover. The two ends of the induction coil are a first output terminal and second output terminal The first output terminal and second output terminal lead to a surface of the cover, where an induction current from the induction coil is outputted.

### FIELD

The subject matter herein generally relates to power supplies.

### BACKGROUND

For providing sufficient electric power to an electronic apparatus such as a portable phone or a notebook computer, the electronic apparatus may be electrically connected to a power socket through a transmission cable and a plug or the electronic apparatus may be electrically connected to a computer in order to acquire electrical power.

Recently, a wireless power transmission technology that is capable of wirelessly supplying power has been developed. The wireless power transmission technology is capable of wirelessly supplying electric power. When an electronic apparatus is placed on a surface of the wireless charging device, the wireless charging device may transfer electric energy to the electronic apparatus in order to charge the electronic apparatus. The coil assembly of the wireless charging device and the coil assembly of the electronic apparatus merely need to be aligned with each other.

### BRIEF DESCRIPTION OF THE DRAWINGS

Implementations of the present technology will now be described, by way of example only, with reference to the attached figures.

FIG. 1 is an isometric view of an embodiment of an electrically powered portable device.

FIG. 2 is an exploded view of the electrically powered portable device shown in FIG. 1.

FIG. 3 is an exploded view of a cover of the electrically powered portable device shown in FIG. 2.

FIG. 4 is an isometric view of the cover of the electrically powered portable device shown in FIG. 3.

FIG. 5 is a cross-sectional view of the electrically powered portable device taken along line V -V of FIG. 1.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “outside” refers to a region that is beyond the outermost confines of a physical object. The term “inside” indicates that at least a portion of a region is partially contained within a boundary formed by the object. The term “substantially” is defined to be essentially conforming to the particular dimension, shape, or other feature that the term modifies, such that the component need not be exact. For example, “substantially cylindrical” means that the object resembles a cylinder, but can have one or more deviations from a true cylinder. The term “comprising,” when utilized, means “including, but not necessarily limited to”; it specifically indicates open-ended inclusion or membership in the so-described combination, group, series and the like.

The present disclosure describes an electrically powered portable device 100.

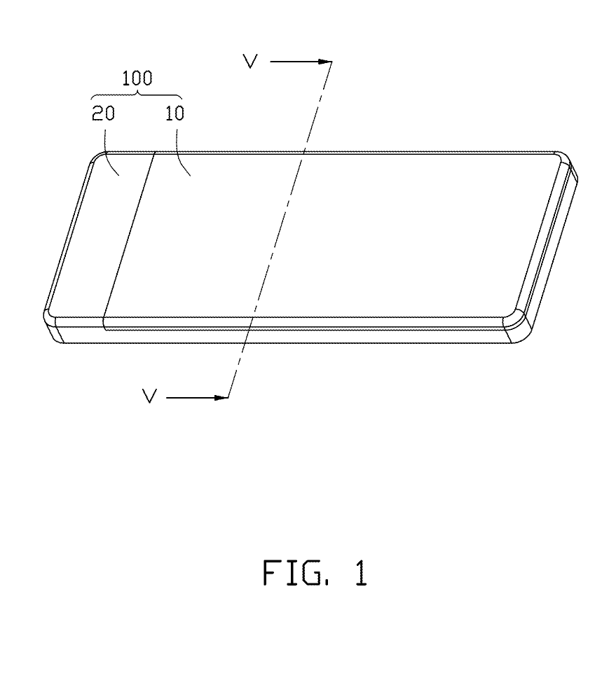

FIG. 1 is an isometric view of an electrically powered portable device 100 according to an embodiment. FIG. 1 illustrates that the electrically powered portable device 100 can include a cover 10 and a main body 20. The cover 10 can be engaged with the main body 20, cooperatively forming a closed single entity.

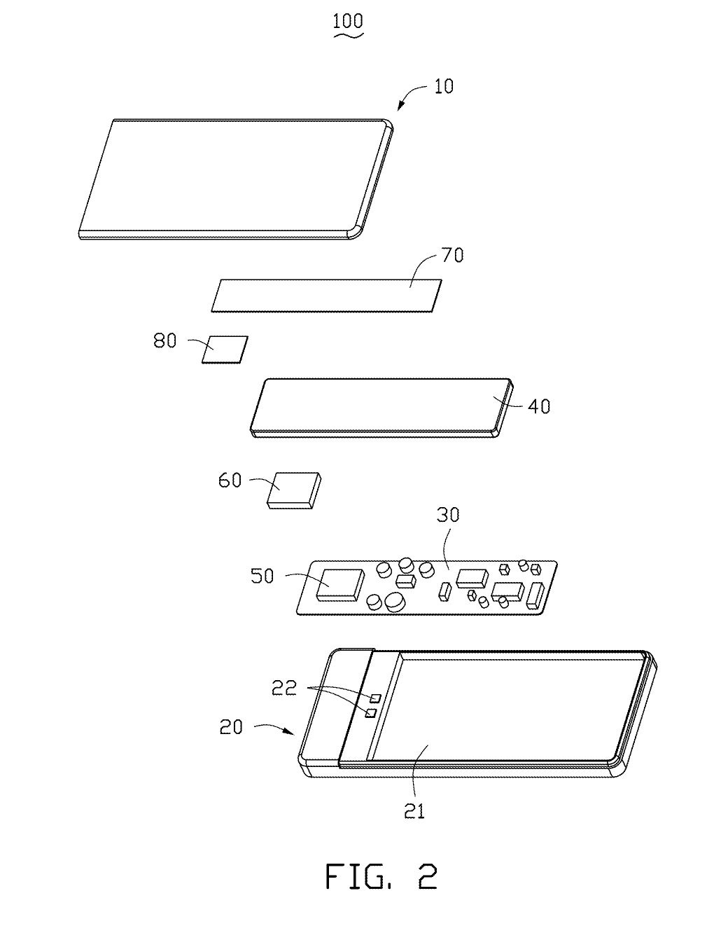

FIG. 2 illustrates that the electrically powered portable device 100 can further include a printed circuit board 30, a power unit 40, a chip card 50, and a shielding casing 60. The printed circuit board 30 and the power unit 40 can be installed in the main body 20. The chip card 50 and shielding casing 60 can be sandwiched between the cover 10 and main body 20.

The main body 20 can include a receiving cavity 21 and two input pads 22. The main body 20 can be a substantially rectangular box. A shape and size of the receiving cavity 21 can substantially match those of the printed circuit board 30 and power unit 40, thereby the printed circuit board 30 and power unit 40 can be received in the receiving cavity 21. In at least one embodiment, the printed circuit board 30 can be positioned adjacent to the power unit 40. The two input pads 22 can be positioned on one end of the main body 20 adjacent to the receiving cavity 21. In at least one embodiment, the two input pads 22 can be spaced from each other for outputting induced current and further providing power to the power unit 40. In at least one embodiment, the power unit 40 can be a battery.

The chip card 50 can be installed on the printed circuit board 30. The shielding casing 60 can be positioned above the chip card 50 for shielding the chip card 50 . The shape and size of the shielding casing 60 can substantially match those of the chip card 50. The shielding casing 60 can be made of a metal. In other embodiments, the shielding casing 60 can be made of other thermally conductive and radiation-resistant materials. The power unit 40 and chip card 50 can generate substantial amounts of heat when working. In other embodiments, one or more heat-generating electrical elements can be included. A section or area defining several heat-generating electrical elements can be regarded as a high heat-generating section.

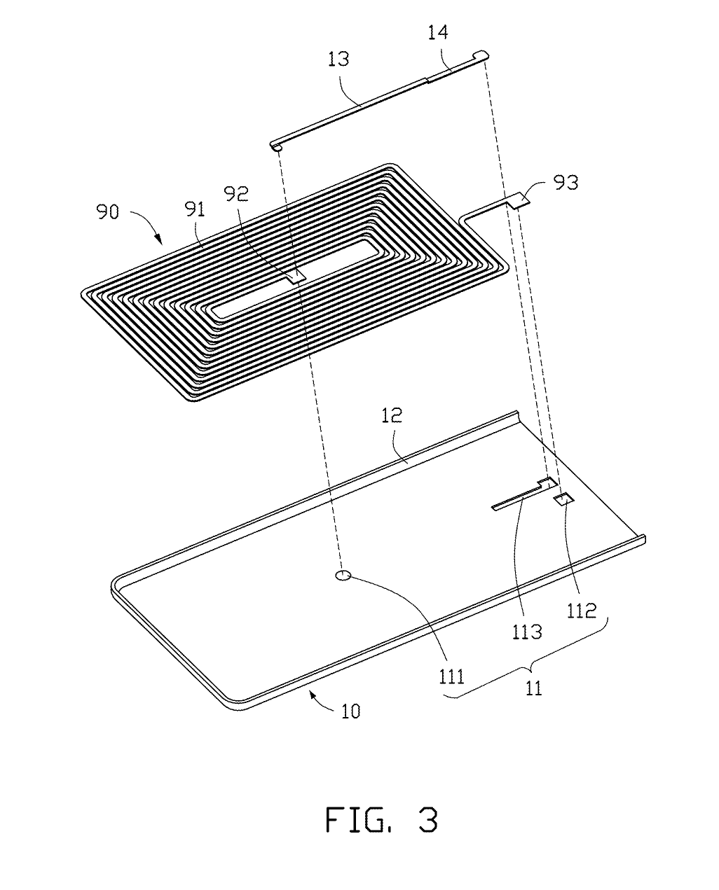

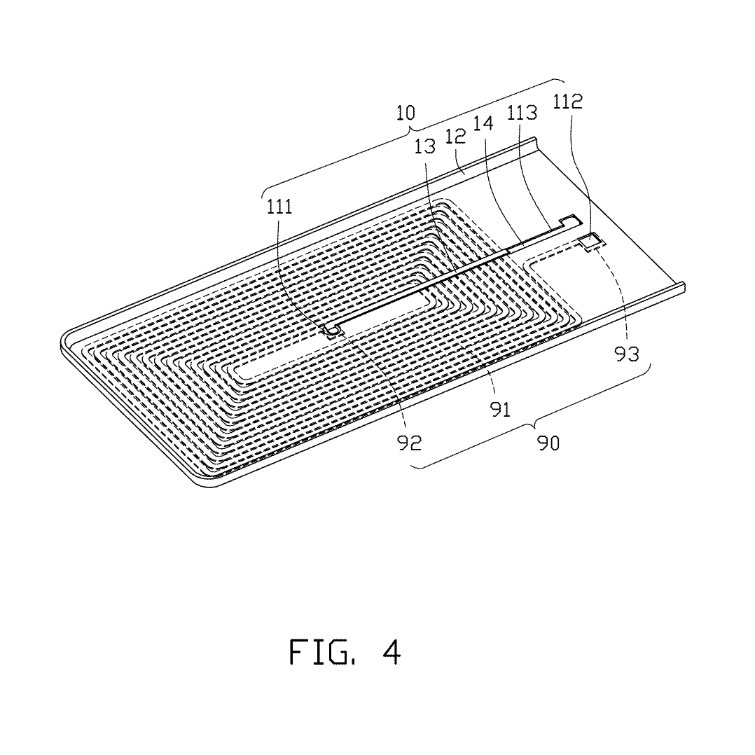

FIG. 3 illustrates an exploded view of the cover 10 (shown in FIG. 2 and FIG. 4). FIGS. 3 and 4 illustrate that the electrically powered portable device 100 can further include an induction coil 90 positioned inside the cover 10. The cover 10 can include a bottom plate 11, three sidewalls 12 enclosing the bottom plate 11, a connecting terminal 13, and a leading terminal 14. The connecting terminal 13 and leading terminal 14 can be attached on the bottom plate 11. The bottom plate 11 can be rectangular. The induction coil 90 can be positioned inside the bottom plate 11. The bottom plate 11 can be integrated with the induction coil 90.

In at least one embodiment, the connecting terminal 13 and leading terminal 14 can be electric metal clip terminals. In other embodiments, the connecting terminal 13 and leading terminal 14 can each be an electric lead. The connecting terminal 13 and leading terminal 14 can be made of a very thin material less than 1 mm. The size and shape of the connecting terminal 13 and leading terminal 14 can substantially match the bottom plate 11.

The bottom plate 11 can include a drawing foot 111, a recessed portion 112, and a groove 113. The recessed portion 112 and groove 113 can be spaced from each other. The recessed portion 112 and groove 113 can be located on an inner surface of the bottom plate 11 facing the receiving cavity 21 (as shown in FIG. 2). The recessed portion 112 can be substantially rectangular. The recessed portion 112 can be defined to receive an end of the induction coil 90 away from the drawing foot 111. The groove 113 can be a strip of material. The shape and size of groove 113 can be to substantially match and receive the leading terminal 14.

In at least one embodiment, the induction coil 90 can be formed as a substantially flat rectangle. The induction coil 90 can include a disk body 91, a first output terminal 92, and a second output terminal 93. The disk body 91 can be parallel with the inner surface of bottom plate 11. The ends of the induction can be respectively defined as the first output terminal 92 and second output terminal 93. The second output terminal 93 can be received in the recessed portion 112. The first output terminal 92 and second output terminal 93 can lead to the inner surface of the cover 10, whereby induction current generated by the induction coil 90 can be outputted to the two input pads 22 (as shown in FIG. 2).

In other embodiments, the induction coil 90 can be formed in a circular, oval, or other shape. In other embodiments, the induction coil 90 can be positioned inside one of the sidewalls 12 or inside the main body 20 (as shown in FIG. 2).

The first output terminal 92 can be connected with the drawing foot 111. One end of the connecting terminal 13 can be electrically connected with the first output terminal 92 by the drawing foot 111. The other end of the connecting terminal 13 away from the drawing foot 111 can be connected with the leading terminal 14. Therefore, the leading terminal 14 can be electrically connected with the first output terminal 92 by the connecting terminal 13. In at least one embodiment, an end of the leading terminal 14 away from the connecting terminal 13 can be defined as an unconnected or open end. Thus, the open end of the leading terminal 14 can lead the induction current from the induction coil 90 to the outside, where the induction current can be outputted. The open end of the leading terminal 14 and second output terminal 93 can be positioned according to the two input pads 22 (as shown in FIG. 2), in order that the induction current can be input to the two input pads 22.

The induction coil 90 can be integrally formed with the cover 10. In at least one embodiment, a thickness of the induction coil 90 across the flat profile can be less than 1 mm. In other embodiments, the induction coil 90 can be made of an electrically-conductive plastic. The induction coil 90 can be made of a thin copper sheet having a thickness less than 3 mm. The induction coil 90 can be integrally formed with the cover 10 by a method of insert molding. The thickness of the induction coil 90 integrated with the cover 10 can be small enough so that the cover 10 retains a very thin profile.

The induction coil 90 can be employed with a wireless charging device (not shown), whereby the wireless charging device can transfer electric energy to the induction coil 90 by induction. Thus, the power unit 40 can be charged from the two input pads 22 and provide electric power to the electrically powered portable device 100 shown in FIG. 2. The electrically powered portable device 100 does not require a transmission cable or a plug. Furthermore, the closed design of the charging structure improves the water resistance and other sealed properties of the electrically powered portable device 100. In addition, the induction coil 90 can dissipate heat generated in the electrically powered portable device 100, whereby the heat dissipation of the electrically powered portable device 100 can be improved and the strength and rigidity of the cover 10 can be enhanced.

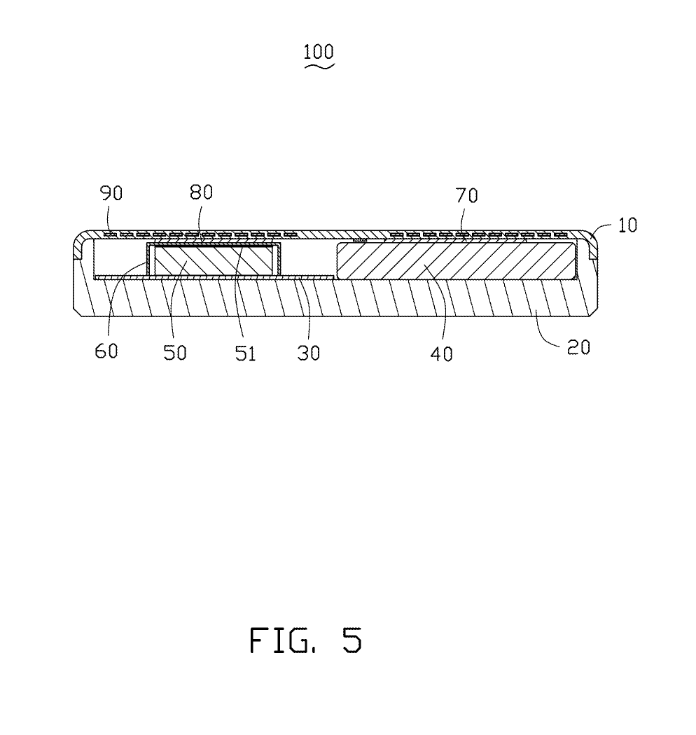

FIG. 5 illustrates that the electrically powered portable device 100 can further include a first thermal pad 51 sandwiched between the chip card 50 and shielding casing 60. The first thermal pad 51 can be attached on the chip card 50. The shape and size of first thermal pad 51 can match those of the chip card 50. In at least one embodiment, the first thermal pad 51 can make contact with the shielding casing 60. The first thermal pad 51 can be defined as a junction between the chip card 50 and shielding casing 60. The heat generated in the chip card 50 can be dissipated to the shielding casing 60 by the first thermal pad 51, whereby a high temperature of the chip card 50 can be reduced.

Furthermore, the electrically powered portable device 100 can include a second thermal pad 70 and a third thermal pad 80. The second thermal pad 70 can be attached on the power unit 40. The third thermal pad 80 can be attached on the shielding casing 60. The second thermal pad 70 can be sandwiched between the power unit 40 and cover 10. The third thermal pad 80 can be sandwiched between the shielding casing 60 and cover 10. The second thermal pad 70 and third thermal pad 80 can be flexible.

In at least one embodiment, the second thermal pad 70 and third thermal pad 80 can each press against the cover 10. Thus, the second thermal pad 70 can diffuse the heat generated from the power unit 40 to the inner surface of the cover 10. The heat generated by the chip card 50 can be dissipated to the first thermal pad 51 and then dissipated to the shielding casing 60. Then, the heat from the first thermal pad 51 can be further dissipated to the third thermal pad 80 and then diffused to the inner surface of the cover 10. The overall temperature of the power unit 40 and chip card 50 can be decreased to avoid temperature-related damage.

In addition, as the induction coil 90 can be made of copper, the induction coil 90 can have a good thermal conduction properties. The heat dissipated from the inner surface of the cover 10 can be further dissipated to the induction coil 90, and from there to the outer environment.

In other embodiments, more than three thermal pads can be included. Furthermore, thermal pads can be positioned on other heat-generating electrical elements. In at least one embodiment, the induction coil 90 can be positioned to face the section or area of high heat. In other embodiments, the induction coil 90 can be integrated with the main body 20.

In assembly, the chip card 50 can be fixed on the printed circuit board 30, and the first thermal pad 51 can be positioned on the chip card 50. Then, the shielding casing 60 can cover the chip card 50 and first thermal pad 51. The printed circuit board 30 and power unit 40 can be secured in the receiving cavity 21 (as shown in FIG. 2). The second thermal pad 70 can be attached on the power unit 40, and the third thermal pad 80 can be attached on the shielding casing 60. Finally, the cover 10 can be coupled to the main body 20. Thus, assembly of the electrically powered portable device 100 can be completed.

As the electrically powered portable device 100 can receive power wirelessly without a plug or a wire, the waterproof properties of the electrically powered portable device 100 can be complete. In addition, as the induction coil 90 of electrically powered portable device 100 can be integrated with the cover 10, the electrically powered portable device 100 can have a smaller thickness and a simple structure.

The embodiments shown and described above are only examples. Many details are often found in the art such as the other features of an electrically powered portable device. Therefore, many such details are neither shown nor described. Even though numerous characteristics and advantages of the present technology have been set forth in the foregoing description, together with details of the structure and function of the present disclosure, the disclosure is illustrative only, and changes may be made in the detail, including in matters of shape, size, and arrangement of the parts within the principles of the present disclosure, up to and including the full extent established by the broad general meaning of the terms used in the claims. It will therefore be appreciated that the embodiments described above may be modified within the scope of the claims.

What is claimed is:

1. An electrically powered portable device comprising:
a cover;
a main body engaged with the cover; and
an induction coil positioned inside the cover;
wherein two ends of the induction on coil are respectively defined as a first output terminal and second output terminal; the first output terminal and second output terminal are leaded to an inner surface of the cover whereby an induction current generated by the induction coil is outputted.

2. The electrically powered portable device as claimed in claim 1, wherein the cover is made of a plastic, and the induction coil is positioned inside the cover by insert molding.

3. The electrically powered portable device as claimed in claim 1, wherein the cover comprises a bottom plate, and the bottom plate comprises a drawing foot connected with the induction coil.

4. The electrically powered portable device as claimed in claim 3, wherein the cover further a connecting terminal electrically connected with the drawing foot; and the connecting terminal is electrically connected with the first output terminal by the drawing foot.

5. The electrically powered portable device as claimed in claim 4, wherein the cover further comprises a leading terminal connected with the connecting terminal;
the bottom plate further comprises a groove; and
the leading terminal is receiving in the groove.

6. The electrically powered portable device as claimed in claim 1, wherein the cover further comprises a recessed portion, and the second output terminal can be positioned in the recessed portion.

7. The electrically powered portable device as claimed in claim 1, wherein the induction coil is less than 1 mm.

8. The electrically powered portable device as claimed in claim 1, wherein the electrically powered portable device comprises at least one electrical elements, and the induction coil is positioned facing the electrical elements.

9. The electrically powered portable device as claimed in claim 8, wherein the electrically powered portable device further comprises at least one thermal pad resisted against the electrical elements .

10. The electrically powered portable device as claimed in claim 9, wherein the electrically powered portable device further comprises a shielding casing positioned above the electrical elements.

11. The electrically powered portable device as claimed in claim 10, wherein each of at least one thermal pad is positioned sandwiched between the shielding casing and the cover.
